(19) United States
(12) Patent Application Publication
(10) Pub. No.: US 2025/0116921 A1
(43) Pub. Date: Apr. 10, 2025

(54) ORIGINAL PLATE, RIBLET MOLDING METHOD, RIBLET TRANSFER SHEET AND METHOD FOR MANUFACTURING THE SAME, AND TOOL

(71) Applicant: NIKON CORPORATION, Tokyo (JP)

(72) Inventor: Yuichi SHIBAZAKI, Kumagaya-shi (JP)

(73) Assignee: NIKON CORPORATION, Tokyo (JP)

(21) Appl. No.: 18/832,037

(22) PCT Filed: Jan. 24, 2022
(86) PCT No.: PCT/JP2022/002439

§ 371 Date: Jul. 22, 2024

(51) Int. Cl. G03F 7/00

(52) U.S. Cl. CPC G03F 7/0002

(57) ABSTRACT

An original plate for transferring a riblet pattern to a resin by an imprinting technique includes a member with a predetermined thickness having one surface on which recessed grooves serving as a plurality of riblets after transfer to the resin are formed with a predetermined interval therebetween, and a plurality of projecting portions protruding from the one surface are disposed on the one surface with a predetermined second interval therebetween wider than the predetermined interval.

### TECHNICAL FIELD

The present invention relates to an original plate, a riblet molding method, a riblet transfer sheet and a method for manufacturing the same, and a tool, and more specifically relates to an original plate for transferring a riblet pattern to a resin by an imprinting technique, a riblet molding method for molding riblets on a surface of an object using the original plate, a riblet transfer sheet and a method for manufacturing the same used for molding a riblet pattern on a surface of an object, and a tool for placing an original plate for transferring a riblet pattern to a resin by an imprinting technique on an object on which a resin layer is formed.

### BACKGROUND ART

It is known that riblet patterns (fine vertical grooves (intervals of approximately 10 μm to 100 μm and heights of approximately 5 μm to 50 μm, as an example in airliners)) provided on surfaces of aircraft, surfaces of watercraft, and the like reduce a turbulent friction resistance of gas or liquid flowing on these surfaces. For example, in small aircrafts, reduction in resistance of approximately 6% has been demonstrated through flight, and reducing the turbulent friction resistance using riblets is expected to greatly contribute to reduction in greenhouse gas emissions and fuel costs.

For example, there are various known technologies for installing riblets on a body of an aircraft. However, all the technologies in the related art are far from being put to practical use in terms of time and costs incurred for installation, durability, and the like. However, in recent years, in order to overcome these shortcomings, a technology in which riblets are directly provided on a body surface by pressing a UV transparent resin female mold against a UV curable paint while performing irradiation with UV rays has been proposed (for example, refer to Patent Document 1).

However, in the technology described in Patent Document 1, from the viewpoint of achieving sufficient aerodynamic characteristics, there is room for further improvement with regard to a tendency of a film thickness of a base layer of riblets to have a gradient, or the like.

### CITATION LIST

### Patent Document

[Patent Document 1]
   Specification of U.S. Pat. No. 7,736,570

### SUMMARY OF INVENTION

### Solution to Problem

According to a first aspect of the present invention, there is provided an original plate for transferring a riblet pattern to a resin by an imprinting technique. The original plate is constituted of a member having one surface on which recessed grooves serving as a plurality of riblets after transfer to the resin are formed with a first predetermined interval therebetween, and a plurality of projecting portions protruding from the one surface are disposed on the one surface with a second predetermined interval therebetween wider than the first predetermined interval.

According to a second aspect of the present invention, there is provided a riblet molding method for molding a riblet pattern on a surface of an object. The object is an object of which a surface comes into contact with a flow of a fluid when in use. The riblet molding method includes forming a resin layer by applying a resin to at least a part on the surface of the object, placing the original plate according to the first aspect on the surface of the object in a state of covering the resin layer and causing a tip surface of each of a plurality of projecting portions to abut the surface of the object, curing the resin layer while the tip surface of each of the plurality of projecting portions of the original plate remains in a state of abutting the surface of the object, and removing the original plate from the surface of the cured resin layer after the resin layer is cured.

According to a third aspect of the present invention, there is provided a riblet transfer sheet used for molding a riblet pattern on an object. The riblet transfer sheet has a three-layer structure in which a base film made of a polymer film, a coating material layer made of a resin, and a water-soluble resin sheet are laminated and integrated. An uneven pattern having a plurality of recessed portions having the same shape as the recessed portions and a plurality of projecting portions having the same shape as the projecting portions is formed on one surface of the water-soluble resin sheet in a disposition similar to that in the original plate according to the first aspect. The coating material layer has riblets and recessed portions corresponding to the uneven pattern.

According to a fourth aspect of the present invention, there is provided a method for manufacturing the riblet transfer sheet according to the third aspect. The method for manufacturing a riblet transfer sheet includes forming the uneven pattern on one surface of a water-soluble resin sheet, placing the base film on an upper surface of a base member and applying a coating material to the upper surface of the base film, overlaying the base film with the water-soluble resin sheet from above in a state where the one surface of the water-soluble resin sheet faces the upper surface of the base film to which the coating material is applied, and forming the coating material layer by curing the coating material while the base film remains in a state of being overlaid with the water-soluble resin sheet from above.

According to a fifth aspect of the present invention, there is provided a riblet molding method for molding a riblet pattern on a surface of an object of which a surface comes into contact with a flow of a fluid when in use. The riblet molding method includes applying a surface coating material to a surface of the object, fixing the riblet transfer sheet according to the third aspect to the object through adhesion and pressurization in a direction in which the base film faces the surface coating material in a state where the surface coating material is uncured, and removing the water-soluble resin sheet after the surface coating material is cured.

According to a sixth aspect of the present invention, there is provided a disassembly/assembly-type tool for suction-holding an original plate for transferring a riblet pattern to a resin by an imprinting technique. The tool includes a plurality of cube-shaped piping joint members, a plurality of support pipings, and a plurality of vacuum pipings as constituent members. The tool is constituted to have a turret shape in its entirety by combining these constituent members. The plurality of piping joint members are disposed two-dimensionally within a predetermined surface. The plurality of support pipings are provided respectively correspondingly to the plurality of piping joint members, and each of the plurality of support pipings is constituted of a vacuum piping in which one end is connected to the corresponding piping joint member and the other end has a vacuum suction pad that is tiltable along a suctioned surface and which extends in a direction orthogonal to the predetermined surface. In each of the plurality of vacuum pipings, one end and the other end are respectively connected to two adjacent piping joint members of the plurality of piping joint members. The original plate is able to be suctioned by the vacuum suction pads respectively provided in the plurality of support pipings. A shape and an area of a region on the suctioned surface of the original plate having the plurality of suction pads disposed therein are able to be freely changed in accordance with a shape and a size of the original plate serving as a suction target by replacing at least some of the plurality of vacuum pipings with vacuum pipings having a different length.

### BRIEF DESCRIPTION OF DRAWINGS

FIG. 1 is a cross-sectional view showing an original plate according to an embodiment of which a part is omitted.

FIG. 2 is an explanatory view of setting a maximum deflection which may occur in the original plate due to an action of a uniformly distributed load.

FIG. 3 is a flowchart showing a flow of processing of a method for molding riblets according to the embodiment.

FIGS. 4(A) to 4(C) are views showing a metal mold. FIG. 4(B) is a plan view schematically showing the metal mold, FIG. 4(A) is a cross-sectional view along line A-A in FIG. 4(B), and FIG. 4(C) is a cross-sectional view along line C-C in FIG. 4(B).

FIGS. 5(A) to 5(C) are explanatory views of a process of manufacturing an original plate using a positive mold (metal mold).

FIG. 6 is a view schematically showing a constitution of a tool for suction-holding an original plate.

FIGS. 7(A) and 7(B) are views showing a situation in which the tool holding the original plate is placed on a wing by a robot arm (not shown) while the original plate is being held.

FIGS. 8(A) to 8(D) are conceptual diagrams showing a flow of processing when the riblets are molded on an upper surface of the wing and are views each corresponding to Step S102 to Step S108 in FIG. 3.

FIGS. 9(A) to 9(D) are schematic cross-sectional views showing a situation of change on the upper surface of the wing until the riblets are molded.

FIG. 10 is a schematic cross-sectional view showing a riblet transfer sheet.

FIG. 11 is a flowchart showing a flow of processing of the method for manufacturing a riblet transfer sheet.

FIG. 12 is a flowchart showing a flow of processing of a method for molding riblets on a riblet molding target using the riblet transfer sheet.

### DESCRIPTION OF EMBODIMENT

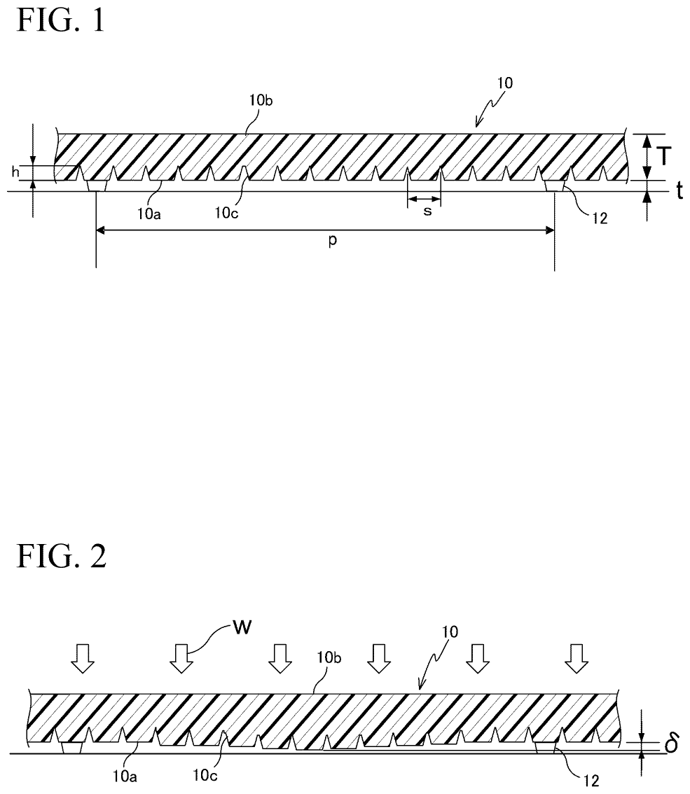

Hereinafter, an embodiment will be described on the basis of FIGS. 1 to 11.

FIG. 1 shows a cross-sectional view of an original plate 10 according to the embodiment of which a part is omitted. The original plate 10 is used for transferring a riblet pattern to a resin by an imprinting technique.

The original plate 10 has a size corresponding to a transfer target part of an object that is a target for riblet molding, and FIG. 1 shows a cutout part thereof.

Regarding objects for molding riblets thereon, there are various objects such as objects of which a surface comes into contact with a flow of a fluid when in use. However, in the present embodiment, a case where riblets are molded on an aircraft will be described.

The original plate 10 is constituted of a rectangular plate-shaped member having a first length in a lateral direction of the paper in FIG. 1 and having a second length in a direction orthogonal to the paper in FIG. 1, for example. The original plate 10 has a first surface 10a and a second surface 10b parallel to each other, and groove-shaped recessed portions 10c having a depth h are formed on the first surface 10a at a predetermined pitch s over the entire length in the lateral direction in the plane of the paper in FIG. 1 (which will hereinafter be suitably referred to as a first direction). For example, the recessed portions 10c are V grooves each having left and right inclined surfaces with a width narrowing from the first surface 10a side toward the second surface 10b side. However, they are not limited to this and may be grooves each provided with a flat surface parallel to the first surface on a bottom surface of the V groove. Alternatively, in place of the left and right inclined surfaces, for example, the recessed portions 10c may be grooves each having a bilaterally symmetrical curved surface with a width narrowing from the first surface 10a side toward the second surface 10b side or may be grooves each having a predetermined depth with a uniform width over the entire region in a depth direction. In addition, a plurality of boss-shaped projecting portions 12 each having a height t are provided on the first surface 10a with a predetermined interval (pitch) p therebetween in the first direction. The plurality of projecting portions 12 are also provided with the pitch p therebetween in the depth direction of the paper in FIG. 1 (which will hereinafter be suitably referred to as a second direction). That is, a plurality of projecting portions 12 are disposed on the first surface 10a in a two-dimensional disposition (in the present embodiment, particularly in a matrix shape) in the first direction and the second direction. The height t of the projecting portion 12 corresponds to the thickness of a base layer of the riblets, which will be described below. In addition, a soft resin, for example, a templating silicone rubber or the like is used as a raw material of the original plate 10. The original plate 10 is not limited to a silicone rubber and need only be made of a soft resin suitable for templating. For example, a water-soluble resin such as a polyvinyl alcohol-based resin can also be used as the raw material thereof. For example, it is desirable that the raw material of the original plate 10 be soft enough to deform along a curved surface when the original plate 10 is placed on an object (member) having a curved surface as its surface, such as a wing or a fuselage of an aircraft. In addition, if a surface of an object for molding riblets thereon is a flat surface, the raw material of the original plate 10 may not be soft and may be a rigid body or the like. In addition, an original plate having a form corresponding to the object for molding riblets thereon is used as the original plate 10. For example, in the case of an aircraft, a sheet-shaped original plate is used. Here, the term “sheet” generally indicates something thin and extensive, is used for spreading, covering, or writing, and is not limited to something like a flimsy film.

For example, the original plate 10 is used for transfer to a resin applied to an object such as a wing of an aircraft. However, at this time, a maximum deflection δ (refer to FIG. 2) occurs at the center position of four adjacent projecting portions 12 respectively disposed at vertex positions of a square shape within the pitch p of the first surface 10a. Here, when a thickness of the original plate 10 (a distance between the first surface 10a and the second surface 10b) is T and a uniformly distributed load (a dead weight, or the sum of a dead weight and an external force) per unit area acting on the original plate 10 during transfer to a resin is w, the value of the maximum deflection δ occurring in the original plate 10 can be considered to be substantially proportional to wp₄/T³. Hence, in the present embodiment, the combination of the parameters w, p, and T is adjusted such that the value of the maximum deflection δ is within a range of approximately 20% or smaller than the height t of the projecting portion 12.

Here, specific dimensions of the pitch s of the recessed portions 10c, the depth h, and the pitch p of the projecting portions 12 of the original plate 10 will be described. The pitch s and the depth h of the recessed portions 10c are set such that the riblets molded on a surface of the object after an uneven pattern of the original plate 10 is transferred to a resin exhibit sufficient performance. For example, in the case of an aircraft, the pitch of the riblets is set to approximately 10 μm to 100 μm. For example, if the pitch of the riblets produced by transferring the original plate 10 to a resin is 100 μm, the pitch s of the recessed portions 10c of the original plate 10 is set to 100 μm correspondingly to this. In this case, for example, the projecting portions 12 are provided at a ratio of one for one hundred recessed portions 10c in a pitch direction of the recessed portions 10c. That is, if the pitch s is 100 μm, the pitch p is set to 10 mm. The pitch s of the recessed portions 10c and the pitch p of the projecting portions 12 are not limited to this. Particularly, since the projecting portions 12 become holes formed in the base layer of the riblets after molding of the riblets (which will be described below), it is desirable that the pitch p be optimized on the basis of the raw material of the original plate 10, for example, the rigidity of a silicone rubber and the transfer pressure such that an influence on aerodynamic characteristics becomes extremely small.

The riblets molded by transferring the V groove-shaped recessed portions 10c disposed at the pitch s as in the original plate 10 are so-called spaced-V groove type. In the case of riblets of this so-called spaced-V groove type, it is desirable to set a height h with respect to the pitch s to a value of approximately h=s/2 from the viewpoint of reducing the resistance that is the sum of the turbulent friction resistance and the pressure resistance. Therefore, for example, the depth h is set to 50 μm.

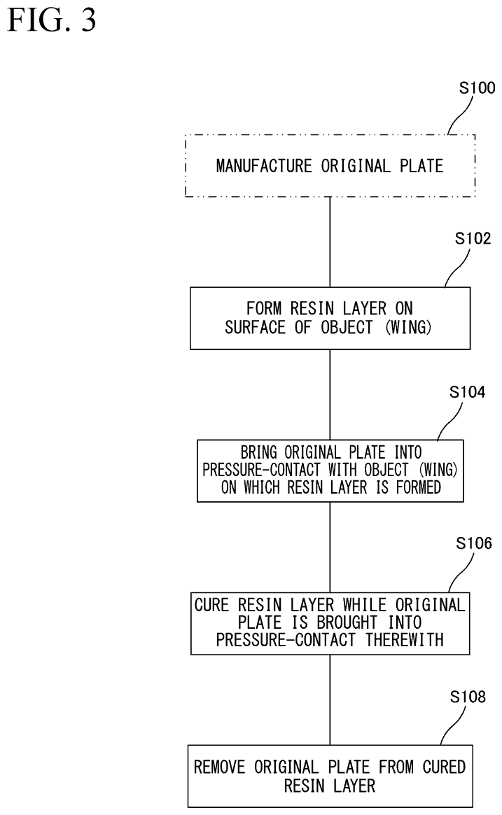

FIG. 3 shows a flowchart showing a flow of processing of a method for molding riblets according to the embodiment.

### <<Process of Manufacturing Original Plate>>

First, a step of manufacturing an original plate (Step S100) in the flowchart of FIG. 3 will be described.

Step S100 includes a process of manufacturing a positive mold and a process of manufacturing the original plate 10 using a manufactured positive mold.

### <Process of Manufacturing Positive Mold>

Here, for example, a case of manufacturing a positive mold (which will hereinafter also be suitably referred to as a metal mold) by finely machining a metal plate such as an aluminum plate or a stainless steel plate will be described.

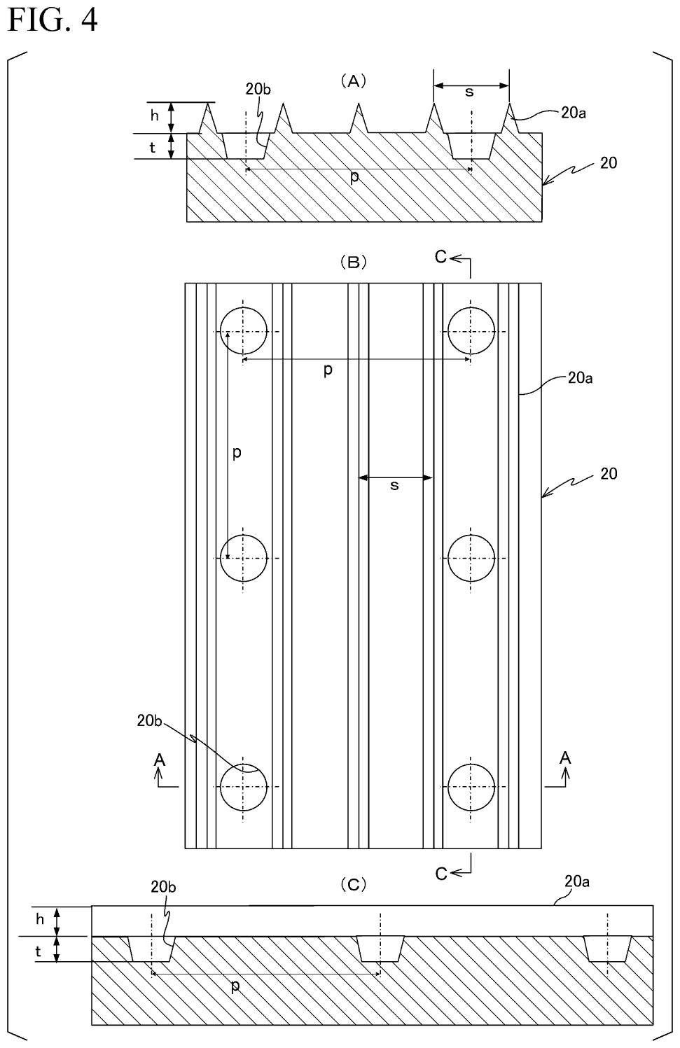

A rectangular metal plate having at least the same size as the manufactured original plate 10 is prepared. A metal mold (positive mold) 20 is produced by forming an uneven pattern as schematically shown in FIGS. 4(A) to 4(C) on a surface (first surface) of the metal plate, for example, with an optical machining device capable of precise machining using an ultra-short pulse laser. FIG. 4(B) is a plan view schematically showing the metal mold 20, FIG. 4(A) is a cross-sectional view along line A-A in FIG. 4(B), and FIG. 4(C) is a cross-sectional view along line C-C in FIG. 4(B). On the upper surface (first surface) of this metal mold 20, a riblet pattern of a so-called spaced-V groove type having a plurality of straight riblets 20a with an isosceles triangular cross section having the pitch s in the first direction (the lateral direction in FIGS. 4(A) and 4(B)) and the height h is formed. In addition, recessed portions (more specifically, truncated conical recessed portions) 20b each having a circular shape in a plan view with a depth t are formed on the first surface at positions between the riblets 20a adjacent to each other at a ratio of one for one hundred riblets 20a. FIGS. 4(A) to 4(C) are schematic views, and therefore the number of riblets, the number of recessed portions, the positional relationship therebetween, and the like differ from actual constitutions. However, the pitch p of the recessed portions 20b is actually set to p=100s. On the first surface, a plurality of recessed portions 20b are also actually formed in a direction orthogonal to the paper in FIG. 4(A) at the pitch p (refer to FIGS. 4(B) and 4(C)).

For the sake of convenience of illustration, FIGS. 4(A) to 4(C) show only five riblets 20a on the first surface of the metal mold 20 and also show one recessed portion 20b for four riblets. However, actually, as described above, many riblets 20a are provided, and the recessed portions 20b are provided at a ratio of one for one hundred riblets 20a.

In the actual process of manufacturing the metal mold 20, as a result of machining by an optical machining device, whether or not the uneven pattern of the metal mold 20 is precisely machined according to in accordance with the design values (within a range of an allowable error) is confirmed through measurement, and correction machining is performed as necessary. In this manner, the metal mold 20 having sufficient precision is prepared.

### <Process of Manufacturing Original Plate 10 Using Positive Mold>

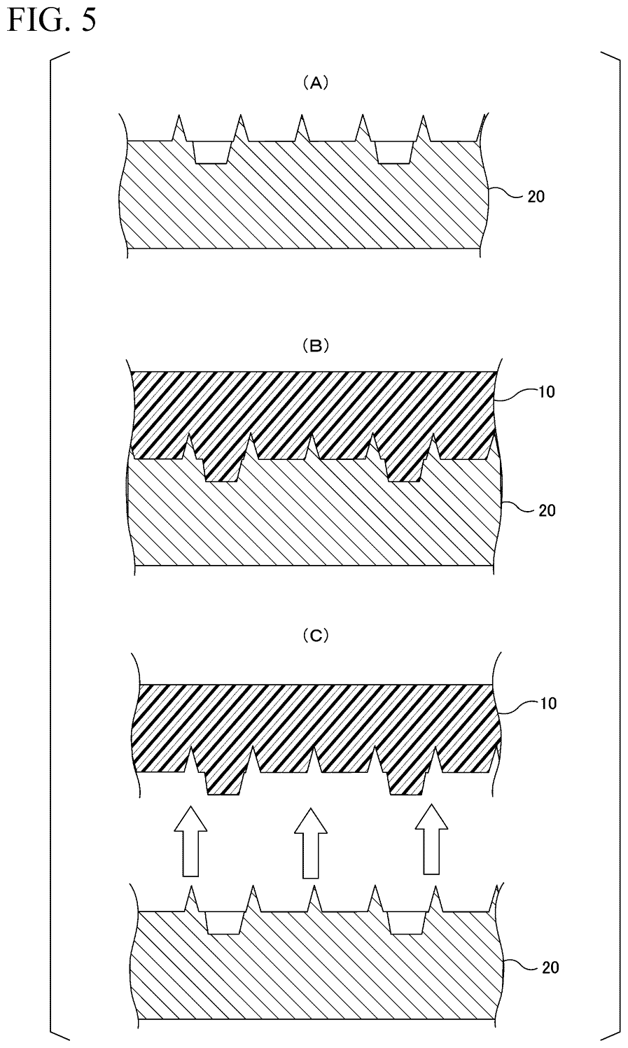

After the surface of the prepared metal mold 20 is blown with air, the metal mold 20 is washed. After washing, the surface of the metal mold 20 is blown with air again to blow off remaining water droplets and is then subjected to natural drying. FIG. 5(A) shows the metal mold 20 after this natural drying.

Next, for example, a liquid mixture of two-component liquid silicone rubber is prepared, and a layer 10 of a liquid mixture having a predetermined thickness is formed by applying the liquid mixture to the entire surface of the metal mold 20. FIG. 5(B) shows the metal mold 20 in which a layer of a liquid mixture is formed on a surface thereof.

Next, the metal mold 20 in which the layer 10 of a liquid mixture of silicone rubber is formed on a surface thereof is input to the inside of a vacuum layer (not shown), and air inside the vacuum layer is evacuated for defoaming. Further, it is left at room temperature until the liquid mixture of silicone rubber solidifies. Further, after the liquid mixture has solidified, as shown in FIG. 5(C), when the solidified silicone rubber is peeled off from the metal mold 20, the peeled off silicone rubber becomes the original plate 10.

### <<Process of Molding Riblets on Object Surface>>

Next, a process of molding riblets on an object surface, that is, Step S102 to Step S108 of the flowchart in FIG. 3 will be described. Here, a case of molding riblets on an upper surface of a wing of an aircraft, for example, a subsonic jet airliner, will be described. This process of molding riblets (Step S102 to Step S108) is executed inside a hangar of an aircraft, for example.

Here, although description is out of order, prior to description of Step S102, a tool 30 for suction-holding the original plate 10 used in a step of transferring (a pattern of) the original plate 10 to a resin layer (Step S104) will be described.

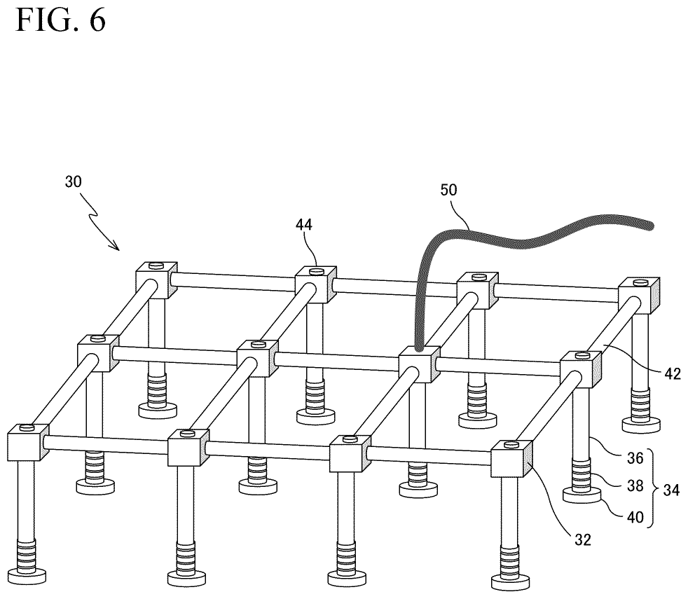

As shown in FIG. 6, the tool 30 is constituted of a turret-shaped structure in its entirety having first number (m×n) vacuum suction pads 40 in a lower end portion thereof. Specifically, as shown in FIG. 6, the tool 30 has first number (m×n) manifold cubes 32 disposed in a matrix shape of m rows and n columns (three rows and four columns in FIG. 6) within a two-dimensional flat surface, first number support pipings 34 respectively having vacuum pipings 36 of which one end (upper end) is individually connected to each of the first number manifold cubes 32, and second number {(m−1)×(n−1)} vacuum pipings 42 respectively coupling the adjacent manifold cubes 32 which belong to the same row or the same column in the matrix. Here, the manifold cubes 32 are cube-shaped manifolds. In the manifold cubes 32, opening portions which also serving as vacuum piping connection portions are formed on four surfaces, five surfaces, or six surfaces thereof. In FIG. 6, one end of a vacuum hose 50 is connected to one particular opening portion on the upper surface of the first number manifold cubes 32. The other end of the vacuum hose 50 is connected to an evacuation device such as a vacuum pump (not shown). In addition, the opening portion on the upper surface of each of all the remaining manifold cubes 32 excluding the foregoing one particular is blocked by a lid member 44. In addition, one end portion of the vacuum piping 42 is detachably connected to the opening portion formed on a side surface of each of the manifold cubes 32. The vacuum suction pad 40 is provided at the other end (lower end) of each of the first number support pipings 34 via a flexible joint 38 having flexibility. Therefore, each of the vacuum suction pads is tiltable along a suctioned surface. In addition, in the tool 30 according to the present embodiment, an adjustment mechanism (not shown) is provided between the flexible joint 38 and the vacuum piping 36 such that the entire length (overall height) of each of all the support pipings 34 can be individually adjusted. This is to make the first surface 10a of the original plate 10 deformable along a curved surface-shaped transfer target region of an object (a target to which the pattern of the original plate 10 is transferred), when the transfer target region of the object is a curved surface other than a flat surface, by suctioning the second surface 10b of the original plate 10 in a state where the heights of suction surfaces of all the vacuum suction pads 40 are adjusted in advance in accordance with the shape of the curved surface. Accordingly, during transfer, the first surface 10a of the original plate 10 can reliably abut the curved surface-shaped transfer target region of an object by placing the original plate 10 on the object in a state where the positional relationship between the original plate 10 suction-held by the tool 30 and the object is adjusted. However, at least some of the support pipings 34 may not be provided with the adjustment mechanism.

As is clear from the foregoing description, the tool 30 according to the present embodiment has the manifold cubes 32, the support pipings 34, and the vacuum pipings 42 as constituent components and is constituted by combining these constituent components as Lego blocks. Therefore, a plurality of constituent components, that is, a plurality of manifold cubes 32, a plurality of support pipings 34, and a plurality of vacuum pipings 42 are individually prepared. Particularly, a plurality of kinds of vacuum pipings 42 having different lengths are prepared. The shape and the area (which can also be referred to as a footprint of the tool 30) of the region on the suctioned surface (second surface 10b) of the original plate 10 where the plurality of vacuum suction pads 40 are disposed can be freely changed by suitably selecting and combining these constituent components and by assembling these constituent components in a manner similar to those above. Accordingly, the original plate 10 having different size and shape can be suction-held. Naturally, the size and the shape of the original plate 10 may be changed in accordance with the size and the shape of the transfer target object.

Next, a step of forming a resin layer on a surface (here, an upper surface) of an object (a wing of an aircraft as an example) (Step S102 of FIG. 3) will be described.

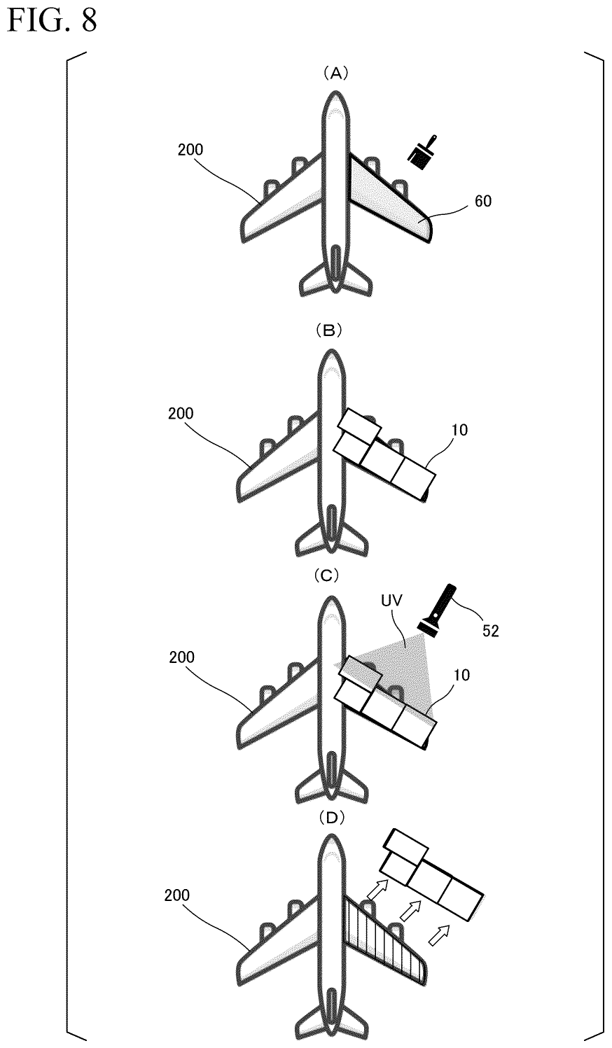

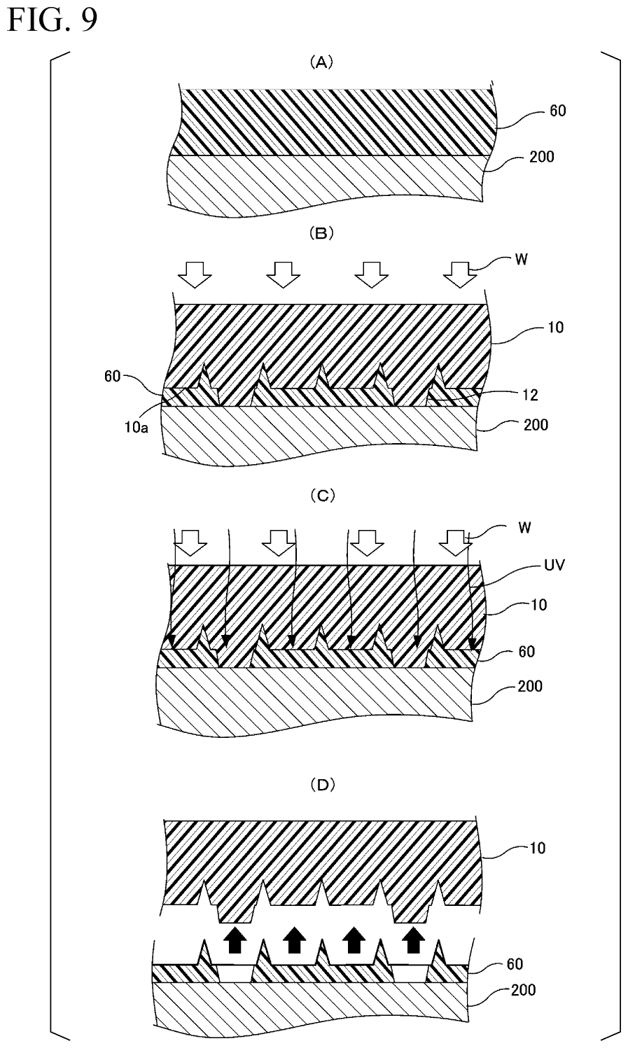

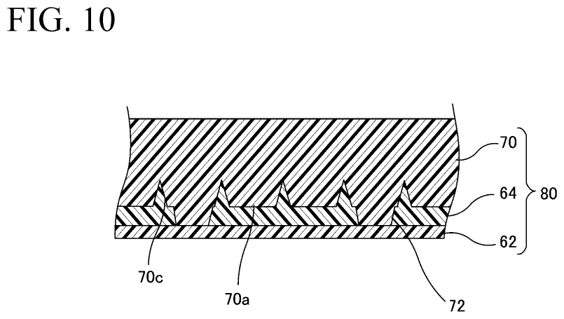

In Step S102 of FIG. 3, as shown in the conceptual diagram of FIG. 8(A), a UV curable resin layer 60 is formed by applying, for example, a liquid UV curable resin to an upper surface (actually, on a paint film (not shown)) of a wing 200 having, for example, an aluminum alloy (or a carbon fiber reinforced plastic (CFRP) or the like) as a raw material (refer to FIG. 9(A)). Here, an acrylic resin in which radicals are generated and polymerization reaction starts when it is irradiated with UV rays, an epoxy resin in which cations (acid) are generated and cationic polymerization reaction starts when it is irradiated with UV rays, or the like can be used as the UV curable resin.

In place of a UV curable resin, for example, a thermosetting resin, such as an unsaturated polyester resin, a vinyl ester resin, or an epoxy, which is cured by heating may be used. Furthermore, a resin which is cured by being left at a normal temperature for a predetermined time or longer can also be used.

In Step S104 of FIG. 3, the object (wing) 200 having a layer 60 formed thereon is overlaid with the original plate 10 from above, and they are brought into pressure-contact with each other. The processing of Step S104 is performed as follows.

As shown in the conceptual diagram of FIG. 8(B), the original plate 10 having a size corresponding to each size of a plurality of divided pieces of the wing 200 is placed by the tool 30 on the UV curable resin layer 60 formed on the upper surface of the wing 200.

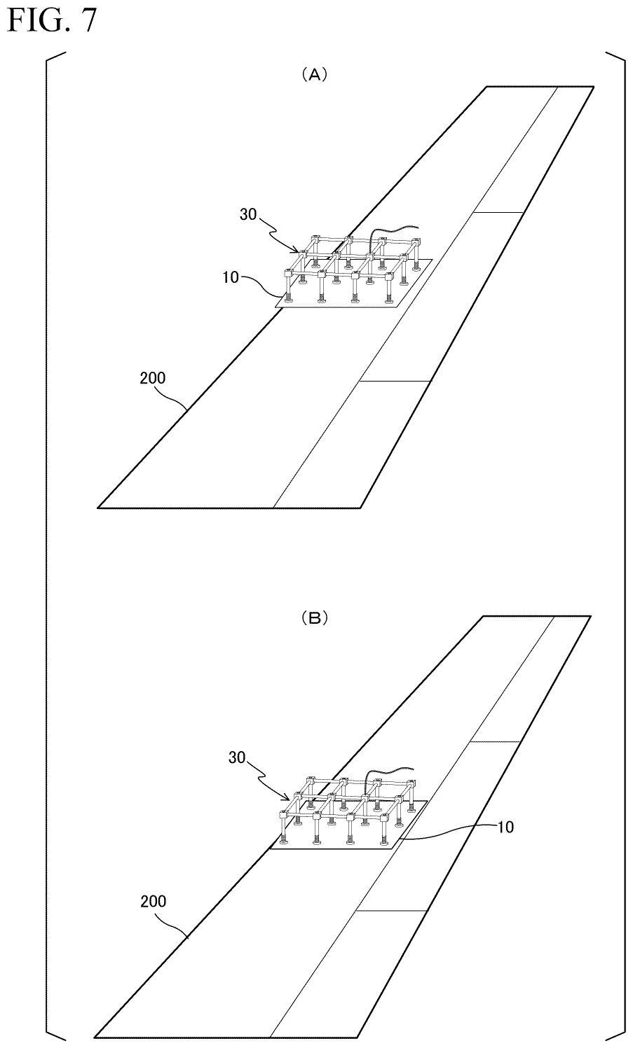

More specifically, as shown in FIG. 7(A), the original plate 10 suction-held by the plurality of vacuum suction pads 40 of the tool 30 is conveyed together with the tool 30 to a location immediately above the wing 200 by a robot arm (not shown) that freely handles the tool 30. Here, on the premise that the tool 30 suction-holds the original plate 10, the positional relationship therebetween is adjusted to a desired positional relationship.

Further, when the original plate 10 is conveyed to the position shown in FIG. 7(A), in a state where the positional relationship between the original plate 10 and the wing 200 is adjusted, the original plate 10 is moved downward together with the tool 30 by the robot arm and is placed on the UV curable resin layer 60 formed on the upper surface of the wing 200 (refer to FIG. 8(B)). Here, adjustment of the positional relationship between the original plate 10 and the wing 200 described above is performed by respectively attaching targets (markers) to the tool 30 suction-holding the original plate 10 and the wing 200, by detecting the targets using, for example, a laser tracker, and by adjusting the position of the tool 30 with respect to the wing 200 by the robot arm on the basis of detection results thereof. Here, the laser tracker is an optical measurement instrument acquiring a three-dimensional position (for seating) of the center position of the target by irradiating a target (a reflector (spherical accessory) or the like is used) attached (or brought into contact with) to the measurement target with laser light and returning laser light reflected by the target to a light emitting source.

As shown in FIG. 7(B), after the tool 30 holding the original plate 10 is placed (mounted) on the wing 200, the robot arm is separated from the tool 30. Accordingly, the original plate 10 is pressurized due to a uniformly distributed load by the dead weight and an external force (the dead weight of the tool 30). FIG. 9(B) shows the positional relationship among the wing 200, the layer 60, and the original plate 10 at this time. In FIG. 9(B), the reference sign w indicates a uniformly distributed load (the dead weight or the sum of the dead weight and an external force) per unit area acting on the original plate 10 during transfer to the resin described above. As shown in this FIG. 9(B), the original plate 10 is pressed against the layer 60 on the wing 200 due to the uniformly distributed load w. However, at this time, in a stage where tip surfaces of the plurality of projecting portions 12 abut the surface of the wing 200 (object), any further approach of the first surface 10a of the original plate 10 to the surface of the wing 200 (object) is inhibited. In a state where the tip surfaces of these projecting portions 12 abut the surface of the wing 200 (object), the part between the original plate 10 and the surface of the wing 200 (object) is in a state of being filled with an uncured UV curable resin. At this time, since the thickness of the layer 60 between the first surface 10a of the original plate 10 and the surface of the wing 200 (object) is regulated by the plurality of projecting portions 12, there is no bias depending on the location, and the thickness is substantially uniform over the entire region.

Next, in Step S106 (FIG. 3), as shown in the conceptual diagram of FIG. 8(C), while the original plate 10 is brought into pressure-contact therewith, the UV curable resin is irradiated with UV rays UV from a UV irradiator 52 with the original plate 10 therebetween. Here, when the tool 30 holding the original plate 10 is placed (mounted) on the wing 200 (refer to FIG. 7(B)), irradiation may be performed with UV rays through gaps of a lattice portion (constituted of a combination of the vacuum pipings and the manifold cubes) constituting a part of the tool 30, and the UV curable resin may be cured as it is. FIG. 9(C) shows a situation, in which the UV curable resin 60 is being cured, corresponding to FIG. 8(C).

When a thermosetting resin is used in place of a UV curable resin, in Step S106, heating is performed with respect to the thermosetting resin in place of irradiation with UV rays.

Next, in Step S108 (FIG. 3), the original plate 10 is removed from the cured resin layer. This original plate 10 is removed by lifting up the original plate 10 together with the tool 30 by the robot arm and peeling off the original plate 10. FIG. 8(D) shows a conceptual diagram of a situation when the original plate 10 is peeled off (removed) from the cured UV curable resin layer 60 on the upper surface of the wing 200. In addition, FIG. 9(D) shows a state after the original plate 10 is peeled off from the cured UV curable resin layer 60. As can be seen from FIGS. 9(D) and 8(D), spaced-V groove-type riblets are molded by a UV resin cured on the upper surface of the wing 200. Since the base layer of these riblets is a cured layer obtained by irradiating the layer 60 shown in FIGS. 9(B) and 9(C) with UV rays, there is no bias in the thickness thereof depending on the location, and the thickness is substantially uniform over the entire region.

When irradiation is performed with UV rays through gaps of the lattice portion (constituted of a combination of the vacuum pipings and the manifold cubes) constituting a part of the tool 30, and the UV curable resin is cured as it is, after the original plate 10 is removed, the regions of the UV curable resin corresponding to the regions respectively suctioned by the plurality of vacuum suction pads 40 may be further cured using UV rays.

When the original plate 10 is formed of a water-soluble resin, in Step S108, the original plate is removed from the cured resin layer by melting the original plate 10 using water.

As described above, according to the present embodiment, since the plurality of projecting portions 12 are formed on the first surface 10a of the original plate 10 together with the plurality of recessed portions 10c, when the original plate 10 is pressed against the layer in order to transfer the uneven pattern of the original plate 10 to the uncured resin layer applied to the surface of the object 200, if the tip surfaces of the projecting portions 12 abut the surface of the object 200, any further approach of the first surface 10a of the original plate 10 to the surface of the object 200 thereafter is inhibited. In addition, since the plurality of projecting portions 12 are disposed two-dimensionally in a predetermined disposition (for example, a matrix shape) having no bias over the entire surface of the first surface 10a, an approach of the first surface 10a of the original plate 10 over the entire surface thereof to the surface of the object 200 by a certain distance or closer is inhibited. As a result, a base layer of riblets having substantially a uniform thickness between the first surface 10a of the original plate 10 and the surface of the object 200, in other words, a base layer in which a tendency of film thickness gradient is not observed is formed (refer to FIG. 9(D)). In addition, according to the present embodiment, since the parameters (the uniformly distributed load w, the pitch p of the projecting portions, a thickness T of the original plate, and the like (refer to FIG. 1)) are set such that the maximum deflection δ of the original plate 10 becomes approximately 20% or smaller than the height t of the projecting portion 12, in this regard as well, a riblet pattern having a base layer with a highly uniform film thickness can be molded.

In addition, according to the present embodiment, since the area of the region of the object surface where riblets are molded at a time can be set in accordance with setting of the size of the original plate 10, compared to a method for molding riblets on a surface of an object which has already been painted and cured using direct laser interference patterning (DLIP) as disclosed in Published Japanese Translation No. 2020-518458 of the PCT International Publication, for example, riblets can be molded over the same area in a much shorter time.

The tool 30 used in the foregoing embodiment is not limited to an original plate having the boss-shaped projecting portions 12 such as the original plate 10 of the foregoing embodiment and is also suitable for handling a negative-type original plate having no projecting portions.

In the foregoing embodiment, a case where riblets of which a reversed pattern is formed in the original plate 10 together with the projecting portions 12 are spaced-V groove-type riblets has been described. However, the embodiment is not limited to this, and a reversed pattern of riblets of a different type may be formed in the original plate 10 together with projecting portions. For example, a reversed pattern of riblets of a V-shape type, a U-shape type, a fence-shape type, or a different type may be formed in the original plate 10 together with projecting portions. Here, V-shaped riblets are riblets that have cross-sectional shapes in which V-shapes are consecutively connected, U-shaped riblets are riblets that have cross-sectional shapes in which rounded U-shapes are consecutively connected, and fence-shaped riblets are riblets that are also referred to as blade riblets and have cross-sectional shapes in which thin fences are arranged. In the foregoing embodiment, the fence-shaped riblets can be molded using the original plate 10 described above in which grooves each having a predetermined depth with a uniform width over the entire region in the depth direction are formed as the recessed portions 10c.

In addition, in the foregoing embodiment, a case where (the peak) of each riblet molded by the imprinting technique using the original plate 10 has a linear shape in a plan view has been described. However, the shape of each riblet in a plan view may be a sine curve shape, a zigzag shape, or the like. The same also applies to riblets of a V-shape type, a U-shape type, a fence-shape type, or a different type. In addition, regarding a riblet type having a triangular cross-sectional shape, triangular riblets may be replaced with riblets having a trapezoidal cross-sectional shape of which the apex portion is cut. In addition, thus far, description has been given on the premise that directions of a plurality of riblets formed in the original plate 10 are the same and the intervals are constant. However, when riblets are molded on a wing of an actual aircraft, the disposition and the directions of the plurality of riblets may be determined on the basis of aerodynamic characteristics obtained by a wind tunnel experiment or a simulation, for example. The foregoing embodiment can be applied to any of the various types described herein by forming a reversed pattern in the original plate 10 together with projecting portions similarly to the foregoing embodiment.

In addition, in the foregoing embodiment, a case where the projecting portions 12 have a boss shape (cylindrical shape) has been described. However, projecting portions are not limited to a cylindrical shape and a cross section thereof may have a tubular shape other than a circular shape.

In the foregoing embodiment, a case where the original plate 10 is manufactured by the imprinting technique using the metal mold 20 has been described. However, the method for manufacturing the original plate 10 is not limited to this. If an uneven pattern having the same shape as the reversed pattern of the riblets and the recessed portions formed in the metal mold 20 described in the foregoing embodiment can be directly formed in the raw material of the original plate 10 by optical machining, machine working, or the like, this may be performed. In this case, using the original plate 10 manufactured (produced) by direct machining, processing of a molding process for a series of riblets from Step S102 to Step S108 may be performed.

In addition, in the foregoing embodiment, riblets are molded on a surface of an object (for example, a wing of an aircraft) that is a target for riblet molding by applying a resin (a UV curable resin or the like) to the surface of the object to form a resin layer and transferring the uneven pattern of the original plate 10 to the resin layer. However, riblets can also be molded on a surface of an object by pasting one surface of a film such as a polymer film, for example, to a surface of an object, applying a resin to the other surface of the film to form a resin layer, and transferring the uneven pattern of the original plate 10 to the resin layer. In this case, a film is pasted to an object using a surface coating material, which will be described below as an example.

### <<Method for Manufacturing Riblet Transfer Sheet>>

Next, a method for manufacturing a riblet transfer sheet used for molding a riblet pattern on a surface of an object will be simply described.

Regarding riblet transfer sheets, a riblet transfer sheet provided with a water-soluble resin sheet having recessed portions for molding riblets on one surface, and a coating material layer formed on the surface having the recessed portions is known (for example, refer to Japanese Unexamined Patent Application, First Publication No. 2018-27510).

Here, an embodiment of a method for manufacturing a riblet transfer sheet having a water-soluble resin sheet and a coating material layer similar to the transfer sheet described in the foregoing publication will be described. Here, the term “sheet” is a general term used in the meaning of something thin and extensive. As long as it has some softness, it is not limited to something flimsy such as a film.

As shown in FIG. 10, a riblet transfer sheet 80 is a sheet having a three-layer structure in which a base film 62 made of a polymer film, a coating material layer 64 made of a resin, and a water-soluble resin sheet 70 made of a water-soluble resin such as a polyvinyl alcohol-based resin, for example, are laminated and integrated. An uneven pattern having a plurality of recessed portions 70c having the same shape and the same size (which will hereinafter be simply referred to as “the same shape”) as the recessed portions 10c described above in a disposition similar to that in the original plate 10 described above, and a plurality of projecting portions 72 having the same shape as the projecting portions 12 described above is formed on a first surface 70a of the water-soluble resin sheet 70. The coating material layer 64 has the riblets and the recessed portions corresponding to the uneven pattern of the water-soluble resin sheet 70.

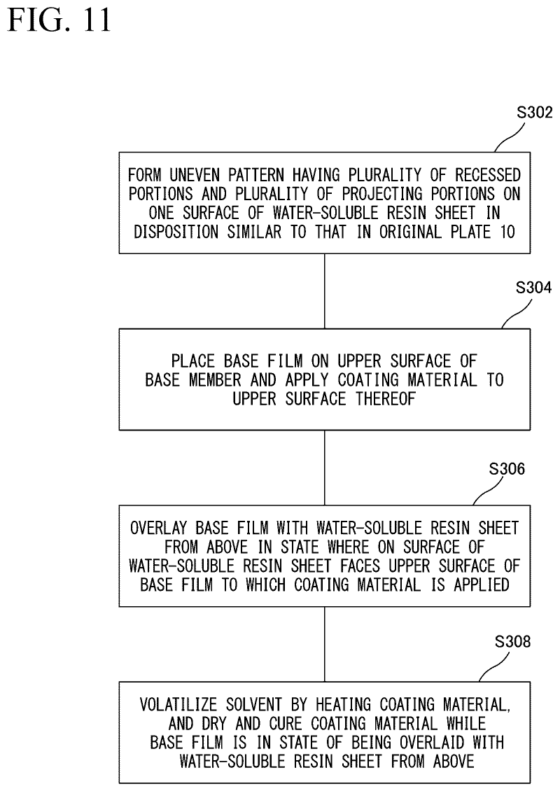

FIG. 11 shows a flowchart showing a flow of processing of a method for manufacturing the riblet transfer sheet 80.

In Step S302 of FIG. 11, an uneven pattern having a plurality of recessed portions 70c and a plurality of projecting portions 72 is formed on one surface (first surface) 70a of the water-soluble resin sheet 70 in a disposition similar to that in the original plate 10 described above. This uneven pattern may be formed using a positive mold having an uneven pattern similar to that of the metal mold 20 described above or may be formed using a heating uneven roller similar to the technology described above in Japanese Unexamined Patent Application, First Publication No. 2018-27510. In the case of the latter, in the heating uneven roller, the foregoing uneven pattern is formed on an outer circumferential surface thereof, and the uneven pattern is formed while the water-soluble resin sheet 70 is moved in synchronization with rotation of the heating uneven roller.

Next, in Step S304, the base film 62 is placed on a favorably flat upper surface of a base member (not shown) in a state of having no deflection, distortion, or the like, and the coating material (liquid resin) 64 is applied to the upper surface of the base film 62. Here, as an example, a heat curing-type material is used as the coating material 64.

Next, in Step S306, the base film 62 is overlaid with the water-soluble resin sheet 70 from above in a state where the first surface of the water-soluble resin sheet 70 faces the upper surface of the base film 62 to which the coating material 64 is applied. At this time, the plurality of projecting portions 72 are in a state of abutting the upper surface of the base film 62 due to action of the dead weight of the water-soluble resin sheet 70.

Next, in Step S308, while the base film 62 is in a state of being overlaid with the water-soluble resin sheet 70 from above, a solvent is volatilized by heating the coating material 64, which is then dried and cured. This process of drying and curing is performed in a drying/curing chamber in which the base member is provided, for example, in the atmosphere at a temperature of 50° C. to 200° C. for 1 to 15 minutes, preferably at a temperature of 80° C. to 150° C. for 2 to 3 minutes. The cured coating material 64 becomes the coating material layer 64 having a base layer with a uniform thickness over the entire surface having a plurality of riblets on a surface on a side opposite to the base film 62 (can also be referred to as a riblet layer). Accordingly, the riblet transfer sheet 80 having a three-layer structure in which the base film 62, the coating material layer 64, and the water-soluble resin sheet 70 are laminated is manufactured.

In the foregoing description, a heat curing-type is used as the coating material, but it is not limited to this. For example, regarding the coating material, a normal temperature dry curing type, a UV dry curing type, or an electron beam dry curing type may be used. In this case, depending on the material kind, the drying/curing chamber may be replaced with a UV irradiation chamber, an electron beam irradiation chamber, or the like. Therefore, regarding the coating material, an alkyd resin-based coating material, an amino alkyd resin-based coating material, an acrylic resin-based coating material, an acrylic-urethane resin-based coating material, an urethane resin-based coating material, an epoxy resin-based coating material, a chlorinated rubber-based coating material, a UV curing coating material, an electron beam curing coating material, a silicone resin-based coating material, a petroleum-based coating material, a vinyl resin-based coating material, a phenolic resin-based coating material, a fluororesin-based coating material, a polyester resin-based coating material, a melamine resin-based coating material, a lacquer-based coating material, or the like can be used. Particularly, in the case of an aircraft, in order to secure impact resistance, weather resistance, solvent resistance, and long-term durability, an alkyd resin-based coating material, an acrylic-urethane resin-based coating material, an urethane resin-based coating material, an epoxy resin-based coating material, a fluororesin-based coating material, a polyester resin-based coating material, or a lacquer-based coating material is preferable, and an urethane resin-based coating material or a fluororesin-based coating material is more preferable.

Next, a method for molding riblets using the riblet transfer sheet 80 described above in the foregoing wing 200 that is a riblet molding target object will be described.

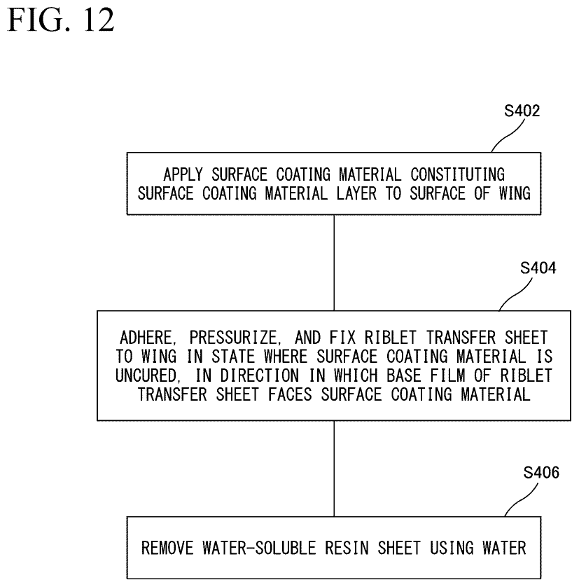

FIG. 12 shows a flowchart showing a flow of processing of this molding method.

First, in Step S402, a surface coating material constituting a surface coating material layer is applied to the surface of the wing 200. The same material as the coating material layer 64 of the riblet transfer sheet may be used or a different material may be used for this surface coating material.

Next, in Step S404, in a state where the surface coating material constituting the surface coating material layer is uncured, in a direction in which the base film 62 of the riblet transfer sheet 80 faces the surface coating material, the riblet transfer sheet 80 is adhered, pressurized, and fixed to the wing 200. Here, an uncured state indicates an incompletely cured state including a semi-cured state. When the riblet transfer sheet 80 is pasted to the surface of the wing 200, the riblet transfer sheet is pasted while being pulled such that riblets are disposed along the flow of the fluid.

After elapse of a predetermined time, the surface coating material constituting the surface coating material layer is cured, and then the water-soluble resin sheet 70 is removed in Step S406 using water. Accordingly, a coating film having riblets is molded on the surface of the wing 200. In the case of an aircraft, the method for molding riblets using a riblet transfer sheet described herein is particularly suitable for the case where riblets are molded on a fuselage surface, or the like.

It goes without saying that the method for molding riblets on an aircraft described above can be retrofitted to not only new aircrafts but also existing aircrafts.

The tool used for pressing the original plate 10 is not limited to the constitution of the foregoing embodiment and may be of a type which applies not only the dead weight of the tool but also a pressing force (external force) to the original plate 10 in addition to the dead weight of the tool.

In the description so far, an aircraft has been described as an object for molding riblets thereon. However, the embodiment is not limited to this. The method for molding riblets using the original plate 10 and the method for molding riblets using the riblet transfer sheet 80 according to the present embodiment can be applied to, for example, ships (hulls, screw, and the like), high-speed trains (Shinkansen, linear motor cars, and the like), racing cars, submarines, rockets, and the like. In addition, it can be applied to high-speed sports such as skiing, sport fields such as swimming, and the like, and can also be applied to ski plates, skiwear, swimsuits, and the like. In addition, it can also be applied to pipelines in which a fluid flows. In addition, it can also be applied to wind turbines for wind power generation and the like.

### REFERENCE SIGNS LIST

10 Original plate
10a One surface
10c Recessed groove
12 Projecting portion
20 Metal mold (positive mold)
30 Tool
32 Manifold cube
34 Support piping
40 Vacuum suction pad
42 Vacuum piping
50 Vacuum hose
60 Resin layer
200 Wing (object)

1-19. (canceled)

20. A mold for transferring a riblet pattern to a resin by an imprinting technique,
wherein the mold is constituted of a member having one surface on which recessed grooves serving as a plurality of riblets after transfer to the resin are formed with a first predetermined interval therebetween, and a plurality of projecting portions protruding from the one surface are disposed on the one surface with a second predetermined interval therebetween wider than the first predetermined interval.

21. The mold according to claim 20,
wherein the recessed grooves are grooves each having a trapezoidal shape or a triangular shape with a predetermined depth in which a width of a cross section orthogonal to a longitudinal direction of the recessed grooves gradually decreases from the one surface side toward the other surface side.

22. The mold according to claim 21,
wherein the plurality of projecting portions are disposed on the one surface at positions away from each other with the second predetermined interval therebetween and at positions between the recessed grooves adjacent to each other.

23. The mold according to claim 22,
wherein the plurality of projecting portions each have a columnar shape having a diameter smaller than the first predetermined interval.

24. The mold according to claim 20,
wherein the recessed grooves are grooves with a predetermined depth in which a width of a cross section orthogonal to a longitudinal direction of the recessed grooves is uniform over the entire region in a depth direction.

25. The mold according to claim 20,
wherein the plurality of projecting portions are disposed on the one surface at positions away from each other with the second predetermined interval therebetween and at positions between the recessed grooves adjacent to each other.

26. The mold according to claim 20,
wherein the plurality of projecting portions each have a columnar shape having a diameter smaller than the first predetermined interval.

27. The mold according to claim 20,
wherein when a target surface for transfer of the riblet pattern of the mold is a curved surface, the member is soft enough to deform along the curved surface due to a dead weight thereof.

28. The mold according to claim 20,
wherein the plurality of projecting portions are disposed two-dimensionally on the one surface.

29. The mold according to claim 28,
wherein the plurality of projecting portions are provided on the one surface in a matrix-shaped disposition.

30. A riblet molding method for molding a riblet pattern on a surface of an object,
wherein the object is an object of which a surface comes into contact with a flow of a fluid when in use, and
the riblet molding method comprises:
forming a resin layer by applying a resin to at least a part on the surface of the object;
placing the mold according to claim 20 on the surface of the object in a state of covering the resin layer and causing a tip surface of each of a plurality of projecting portions to abut the surface of the object;
curing the resin layer while the tip surface of each of the plurality of projecting portions of the mold remains in a state of abutting the surface of the object; and
removing the mold from the surface of the cured resin layer after the resin layer is cured.

31. The riblet molding method according to claim 30,
wherein the resin layer is a layer made of a photocurable resin,
the mold has light transmitting properties,
the curing includes curing the resin layer by irradiating the resin layer with light via the mold, and
the removing includes peeling off the mold from the cured resin layer.

32. The riblet molding method according to claim 30,
wherein the resin layer is a layer made of a thermosetting resin,
the curing includes curing the resin layer through heating, and
the removing includes peeling off the mold from the cured resin layer.

33. The riblet molding method according to claim 30,
wherein the mold is made of a water-soluble resin, and
in the removing, the mold is removed from the surface of the cured resin layer by melting the mold using water.

34. The riblet molding method according to claim 30 further comprising:
manufacturing the mold by an imprinting technique before the resin layer is formed.

35. The riblet molding method according to claim 34,
wherein manufacturing the mold includes
preparing a positive mold in which riblets corresponding to the plurality of recessed grooves and recessed portions corresponding to the plurality of projecting portions formed on the one surface of the mold are formed on the one surface with a positional relationship corresponding to the plurality of recessed grooves and the plurality of projecting portions,
forming a resin layer having a predetermined thickness by applying a templating resin material on the one surface of the positive mold,
solidifying the resin layer by leaving for a predetermined time, and
separating the solidified resin layer from the positive mold after elapse of the predetermined time.

36. A riblet transfer sheet used for molding a riblet pattern on an object,
wherein the riblet transfer sheet has a three-layer structure in which a base film made of a polymer film, a coating material layer made of a resin, and a water-soluble resin sheet are laminated and integrated,
an uneven pattern having a plurality of recessed portions having the same shape as the recessed portions and a plurality of projecting portions having the same shape as the projecting portions is formed on one surface of the water-soluble resin sheet in a disposition similar to that in the mold according to claim 20, and
the coating material layer has riblets and recessed portions corresponding to the uneven pattern.

37. A method for manufacturing the riblet transfer sheet according to claim 36 comprising:
forming the uneven pattern on one surface of a water-soluble resin sheet;
placing the base film on an upper surface of a base member and applying a coating material to the upper surface of the base film;
overlaying the base film with the water-soluble resin sheet from above in a state where the one surface of the water-soluble resin sheet faces the upper surface of the base film to which the coating material is applied; and
forming the coating material layer by curing the coating material while the base film remains in a state of being overlaid with the water-soluble resin sheet from above.

38. A riblet molding method for molding a riblet pattern on a surface of an object of which a surface comes into contact with a flow of a fluid when in use, the riblet molding method comprising:
applying a surface coating material to a surface of the object;
fixing the riblet transfer sheet according to claim 36 to the object through adhesion and pressurization in a direction in which the base film faces the surface coating material in a state where the surface coating material is uncured; and
removing the water-soluble resin sheet after the surface coating material is cured.

39. A disassembly/assembly-type tool for suction-holding a mold for transferring a riblet pattern to a resin by an imprinting technique, the tool comprising:
a plurality of cube-shaped piping joint members, a plurality of support pipings, and a plurality of vacuum pipings as constituent members,
wherein the tool is constituted to have a turret shape in its entirety by combining these constituent members,
the plurality of piping joint members are disposed two-dimensionally within a predetermined surface,
the plurality of support pipings are provided respectively correspondingly to the plurality of piping joint members, and each of the plurality of support pipings is constituted of a vacuum piping in which one end is connected to the corresponding piping joint member and the other end has a vacuum suction pad that is tiltable along a suctioned surface and which extends in a direction orthogonal to the predetermined surface,
in each of the plurality of vacuum pipings, one end and the other end are respectively connected to two adjacent piping joint members of the plurality of piping joint members,
the mold is able to be suctioned by the vacuum suction pads respectively provided in the plurality of support pipings, and
a shape and an area of a region on the suctioned surface of the mold having the plurality of suction pads disposed therein are able to be freely changed in accordance with a shape and a size of the mold serving as a suction target by replacing at least some of the plurality of vacuum pipings with vacuum pipings having a different length.

40. The tool according to claim 39,
wherein in order to place a mold on an object on which a resin layer is formed, the mold is suctioned by the vacuum suction pads respectively provided in the plurality of support pipings,
the mold is constituted of a member having one surface on which recessed grooves serving as a plurality of riblets after transfer to the resin are formed with a first predetermined interval therebetween, and a plurality of projecting portions protruding from the one surface are disposed on the one surface with a second predetermined interval therebetween wider than the first predetermined interval.
